(19) United States
(12) Patent Application Publication
(10) Pub. No.: US 2026/0043833 A1
(43) Pub. Date: Feb. 12, 2026

(54) ELECTRONIC TEST DEVICE WITH NEGATIVE-PRESSURE-TYPED CONTACT ALIGNMENTS

(71) Applicant: CHROMA ATE INC., Taoyuan City (TW)

(72) Inventors: Po-Kai CHENG, Taoyuan City (TW); Su-Chen TAO, Taoyuan City (TW)

(21) Appl. No.: 19/209,791

(22) Filed: May 16, 2025

(30) Foreign Application Priority Data
Aug. 12, 2024 (TW) 113208658

(51) Int. Cl. G01R 1/073; G01R 1/067

(52) U.S. Cl. CPC G01R 1/07378; G01R 1/06716

(57) ABSTRACT

An electronic test device with negative-pressure-typed contact alignment includes a test platform, a circuit load board, an annular elastic structure, a probe module and an airway assembly. The circuit load board loads and electrically connects to a device under test. The annular elastic structure is sandwiched between the test platform and the circuit load board, so that an internal space enclosed by the annular elastic structure and sandwiched between the test platform and the circuit load board becomes airtight. The probe module is disposed on the test platform and partially extends into the internal space. The airway assembly is located on the test platform and connected to the internal space.

### RELATED APPLICATIONS

This application claims priority to Taiwanese Application Serial Number 113208658, filed Aug. 12, 2024, which is herein incorporated by reference.

### BACKGROUND

### Field of Invention

The present disclosure relates to an electronic test device. More particularly, the present disclosure relates to an electronic test device with negative-pressure-typed contact alignments.

### Description of Related Art

A conventional testing device includes a working module and a detection board. The detection board covers a probe head disposed on the working module, and conductive contact points of the detection board are respectively contacted by plural probes of the probe head. Therefore, the working module is allowed to transmit testing signals to a device under test (DUT) on the detection board through the probe head, so as to perform related electrical detection work.

However, since the size of the detection board is quite large and all of the probes of the probe head are quite precise, the conventional method that is implemented alone cannot fully and accurately improve the detection board to align the probes of the probe head with the conductive contact points of the detection board accurately, so as to result in inaccurate test performance.

As seen above, the aforementioned technology is still accompanied with inconveniences and defects, and needed to be further improved.

### SUMMARY

One aspect of the present disclosure is to provide an electronic test device with negative-pressure-typed contact alignments for solving the difficulties mentioned above in the prior art.

In one embodiment of the present disclosure, an electronic test device with negative-pressure-typed contact alignment includes a test platform, a circuit load board, an annular elastic structure, at least one probe module and an airway assembly. The circuit load board loads and electrically connects to a device under test. The annular elastic structure is sandwiched between the test platform and the circuit load board, so that an internal space that is enclosed by the annular elastic structure and sandwiched between the test platform and the circuit load board becomes airtight. The probe module is disposed on the test platform and partially extending into the internal space. The airway assembly is disposed on the test platform and connected to the internal space. When the internal space is evacuated through the airway assembly so as to drive the circuit load board to compress the annular elastic structure and the internal space toward the test platform, the circuit load board is pressed to be electrically connected to the probe module.

In one embodiment of the present disclosure, In one embodiment of the present disclosure, an electronic test device with negative-pressure-typed contact alignment includes a test platform, a circuit load board, an annular elastic structure, a plurality of vacuum channels, at least one probe module and an airway assembly. The circuit load board loads and electrically connects to a device under test. The annular elastic structure is sandwiched between the test platform and the circuit load board, so that an internal space that is airtight is collectively formed by the test platform, the circuit load board and the annular elastic structure. The vacuum channels are formed on the annular elastic structure to be in communication with the internal space, respectively. The probe module is disposed on the annular elastic structure and partially extends into one part of the internal space between the circuit load board and the annular elastic structure. The airway assembly is disposed on the test platform, and communicated with the part of the internal space through the vacuum channels. The airway assembly evacuates the internal space to allow the circuit load board to press and conduct to the probe module.

Thus, through the construction of the embodiments above, the electronic test device with negative-pressure-typed contact alignments is able to make the circuit load board descending accurately and smoothly, so as to accurately complete the alignment of the probes of the probe head and the conductive contacts of the circuit load board, thereby improving the accuracy of the test performance.

The above description is merely used for illustrating the problems to be resolved, the technical methods for resolving the problems and their efficacies, etc. The specific details of the present disclosure will be explained in the embodiments below and related drawings.

### BRIEF DESCRIPTION OF THE DRAWINGS

The disclosure can be more fully understood by reading the following detailed description of the embodiment, with reference made to the accompanying drawings as follows.

FIG. 1 is a sectional schematic view of an electronic test device with negative-pressure-typed contact alignments according to one embodiment of the present disclosure, and a partial enlarged view of an area M shown in the sectional schematic view.

FIG. 2 is an exploded view of the electronic test device of FIG. 1.

FIG. 3 is a top view of a combination of the annular elastic structure and the probe module of FIG. 1.

FIG. 4 is an operated schematic view of the electronic test device of FIG. 1.

FIG. 5 is a sectional schematic view of an electronic test device with negative-pressure-typed contact alignments according to one embodiment of the present disclosure.

FIG. 6 is a cross-sectional view of FIG. 6 along a line AA.

### DETAILED DESCRIPTION

Reference will now be made in detail to the present embodiments of the present disclosure, examples of which are illustrated in the accompanying drawings. Wherever possible, the same reference numbers are used in the drawings and the description to refer to the same or like parts. According to the embodiments, it will be apparent to those skilled in the art that various modifications and variations can be made to the structure of the present disclosure without departing from the scope or spirit of the present disclosure.

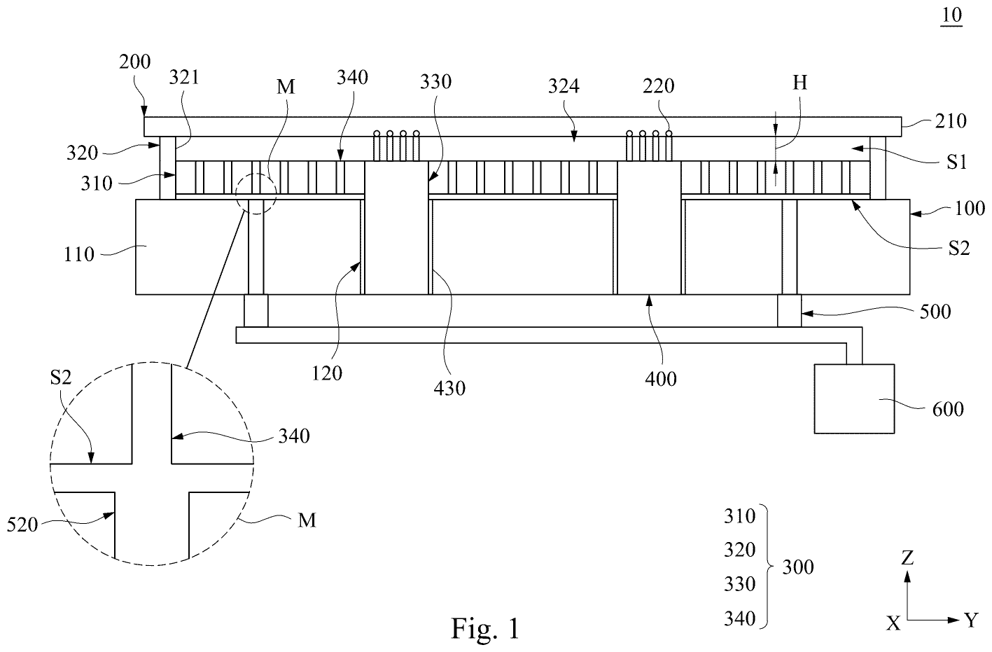

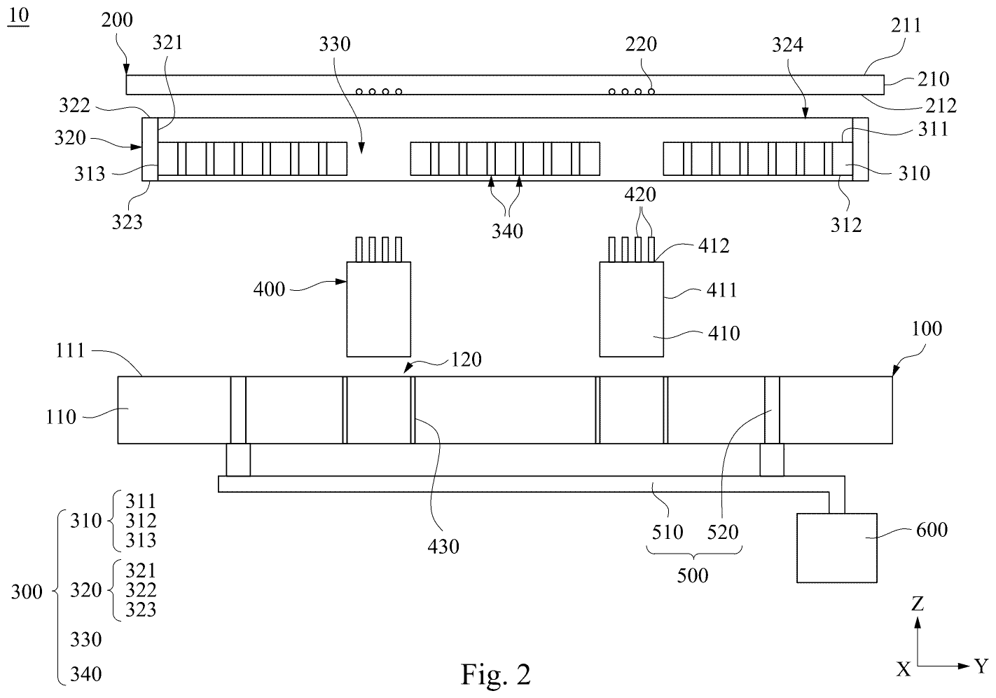

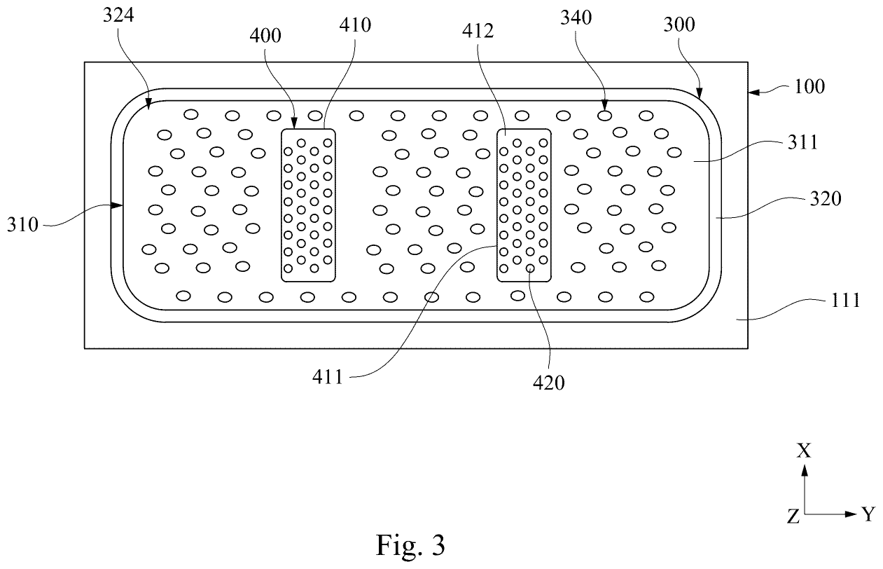

Reference is now made to FIG. 1A to FIG. 3 in which FIG. 1 is a sectional schematic view of an electronic test device 10 with negative-pressure-typed contact alignments according to one embodiment of the present disclosure, and a partial enlarged view of an area M shown in the sectional schematic view, FIG. 2 is an exploded view of the electronic test device 10 of FIG. 1, and FIG. 3 is a top view of the combination of the annular elastic structure 300 and the probe module 400 of FIG. 1 after seeing through the circuit load board 200.

As shown in FIG. 1 and FIG. 2, in the embodiment, the electronic test device 10 includes a test platform 100, a circuit load board 200, an annular elastic structure 300, a plurality of probe modules 400 and an airway assembly 500. The circuit load board 200 is used to load and electrically connect to a device under test (called DUT hereinafter), and the DUT for example may be an electronic component (not shown in Figures). The annular elastic structure 300 is compressible, and completely enclosed to form an internal space 324 therein. The annular elastic structure 300 is sandwiched between the test platform 100 and the circuit load board 200, so that the internal space 324 arranged between the test platform 100 and the circuit load board 200 becomes airtight. The probe modules 400 are respectively disposed on the test platform 100. Each of the probe modules 400 partially extends into the internal space 324 to conduct the circuit load board 200. The airway assembly 500 is disposed on the test platform 100 and connected to the internal space 324.

More specifically, in this embodiment, as shown in FIG. 1 and FIG. 2, the test platform 100 includes a base 110 and a plurality of placement openings 120. An interior space of the base 110 is used to accommodate a test module (not shown in Figures) which is able to test the DUT. The placement openings 120 are spaced recessed on the top portion 111 of the base 110 and in communication with the interior space of the base 110, respectively. A part of each of the probe modules 400 is inserted into one of the placement openings 120, and electrically connected to the test module inside the base 110, and the other part of each of the probe modules 400 extends towards the circuit load board 200 from the corresponding placement opening 120.

The circuit load board 200 includes a wiring board 210 and a plurality of contacts 220. The wiring board 210 is provided with a top surface 211 and a bottom surface 212 which are opposite to each other. The contacts 220 are distributed on a bottom surface 212 of the wiring board 210. The DUT is placed on the top surface 211 of the wiring board 210, and electrically conducted with the contacts 220 through the wiring board 210.

The annular elastic structure 300 includes an intermediate plate 310, an elastic airtight ring 320 and a plurality of vacuum channels 340. The elastic airtight ring 320 surrounds to define the internal space 324. The intermediate plate 310 is located within the internal space 324 and disposed between the test platform 100 and the circuit load board 200.

In more detail, the intermediate plate 310 is in a plate shape, and extended along the XY axis direction. The intermediate plate 310 includes a first surface 311 and a second surface 312 which are opposite to each other, wherein the first surface 311 is faced towards the circuit load board 200, and the second surface 312 is faced towards the test platform 100 and separated from the top portion 111 of the base 110. In the present embodiment, the intermediate plate 310 is a fiberglass board, however, the present disclosure is not limited thereto.

The elastic airtight ring 320 completely encloses and fixedly connects to the intermediate plate 310. In more detail, the outer side 313 of the intermediate plate 310 is directly and fixedly connected to the inner wall 321 of the elastic airtight ring 320, and located between the upper side 322 and the lower side 323 of the elastic airtight ring 320. The elastic airtight ring 320 is directly sandwiched between the test platform 100 and the circuit load board 200 along the Z axis, so that a first air gap S1 is jointly defined by the bottom surface 212 of the wiring board 210, the first surface 311 of the intermediate plate 310 and the elastic airtight ring 320 together, and a second air gap S2 is jointly defined by the top portion 111 of the base 110, the second surface 312 of the intermediate plate 310 and the elastic airtight ring 320 together.

In the present embodiment, more specifically, the upper side 322 of the elastic airtight ring 320 can be removably contacted with the wiring board 210 of the circuit load board 200, and the lower side 323 is fixedly connected to the base 110 of the test platform 100. The wiring board 210 is located between the first air gap S1 and the second air gap S2, and the size of the first air gap S1 is larger than the size of the second air gap S2. However, the present disclosure is not limited to this. In the present embodiment, the elastic airtight ring 320 is a rubber or silicone product, and the interior of the elastic airtight ring 320 is hollow, however, the present disclosure is not limited thereto.

The vacuum channels 340 are evenly distributed on the intermediate plate 310 (FIG. 3), and two opposite ends of each of the vacuum channel 340 are respectively connected to the first surface 311 and the second surface 312 of the intermediate plate 310, and respectively connected to the first air gap S1 and the second air gap S2. In the present embodiment, the vacuum channels 340 are respectively spaced arranged to surround the probe modules 400 (FIG. 3), however, the present disclosure is not limited thereto.

It is noted, when the number and density of the vacuum channels 340 on the intermediate plate 310 are greater, the circuit load board 200 can be vertically descended more accurately and smoothly, thereby achieving more precise contact alignments of the probe modules 400 and the circuit load board 200.

In addition, the annular elastic structure 300 further includes a plurality of through holes 330. The through holes 330 are formed on the intermediate plate 310 at intervals and respectively aligned with and connected to the placement openings 120. Each of the through holes 330 is penetrated through the intermediate plate 310 to be connected to the first surface 311 and the second surface 312 of the intermediate plate 310, respectively.

In this embodiment, one part of each of the probe modules 400 is collectively inserted into the through hole 330 and the placement opening 120 which are corresponded to each other, that is, another portion of each of the probe modules 400 passes through the through hole 330 and continues to extend from the first surface 311 of the intermediate plate 310 to the bottom surface 212 of the circuit load board 200. Furthermore, each of the probe modules 400 includes a module body 410 and a plurality of compression probes 420. Each of the compression probes 420 is retractably installed on an end surface 412 of the module body 410. One end of each of the compression probes 420 is directly contacted with one of the contacts 220 of the circuit load board 200.

In the embodiment, each of the probe modules 400 is further provided with an airtight collar 430 sheathed around an outer surface 411 of the module body 410 of the probe module 400. When the module body 410 is inserted into the corresponding placement opening 120, the airtight collar 430 is clamped between the module body 410 and the test platform 100 so as to disconnect a communication between the second air gap S2 and the placement opening 120.

The airway assembly 500 includes at least one collecting channel 510 and a plurality of branching channels 520. These branching channels 520 are distributed at intervals in the base 110 of the test platform 100. One end of each of the branching channels 520 is in communication with the second air gap S2, and the other end thereof is in communication with the collecting channel 510. One end of the collecting channel 510 away from the second air gap S2 is in communication with a vacuum generating device 600. In this way, the vacuum generating device 600 can be in communication with the airway assembly 500, the second air gap S2, the vacuum channels 340 and the first air gap S1. In this embodiment, the collecting channel 510 and the branching channels 520 of the airway assembly 500 are formed together as a whole tube body, or a ventilation groove in the test platform 100, however, the disclosure is not limited thereto.

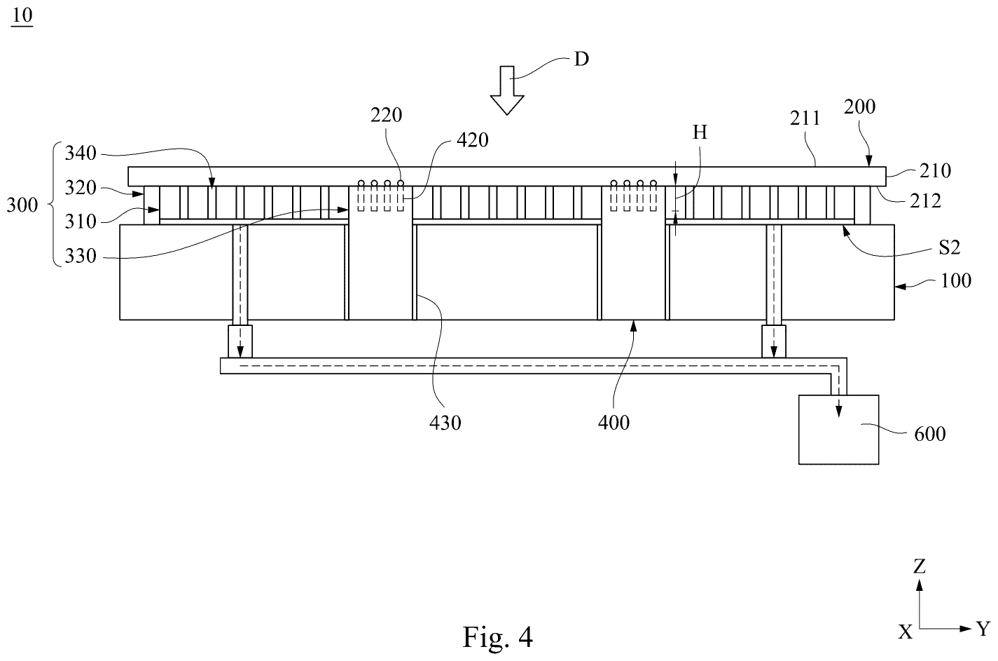

FIG. 4 is an operated schematic view of the electronic test device 10 of FIG. 1. Thus, as shown in FIG. 1 and FIG. 4, when the vacuum generating device 600 is triggered to evacuate the internal space 324 (i.e., the second air gap S2, the vacuum channels 340 and the first air gap S1) through the airway assembly 500, the air in the first air gap S1 begins to be drawn into the second air gap S2 through all of the vacuum channels 340, and then transmitted to the vacuum generating device 600 through the airway assembly 500, thereby generating a negative pressure in the internal space 324.

At the same time, since the negative pressure generated in the internal space 324, the suction force of the vacuum generating device 600 drives the circuit load board 200 to descend vertically in the direction D along the Z-axis towards the test platform 100, thereby vertically compressing the first air gap S1 and the annular elastic structure 300. Therefore, the circuit load board 200 begins to press the probe modules 400 downwardly and electrically connect the probe modules 400, respectively.

Furthermore, when the internal space 324 is evacuated, the contacts 220 of the circuit load board 200 respectively press all or at least part of the compression probes 420 to be retreated into the module body 410 and electrically contacted with the compression probes 420.

In the present embodiment, for example, each of the compression probe 420 has a compression stroke (reference height H), and the length of the compression stroke is the same as the height H of the first air gap S1, that is, when the contacts 220 of the circuit load board 200 presses the entire compression probes 420 into the module body 410, the bottom surface 212 of the circuit load board 200 is directly flat attached the first surface 311 of the intermediate plate 310.

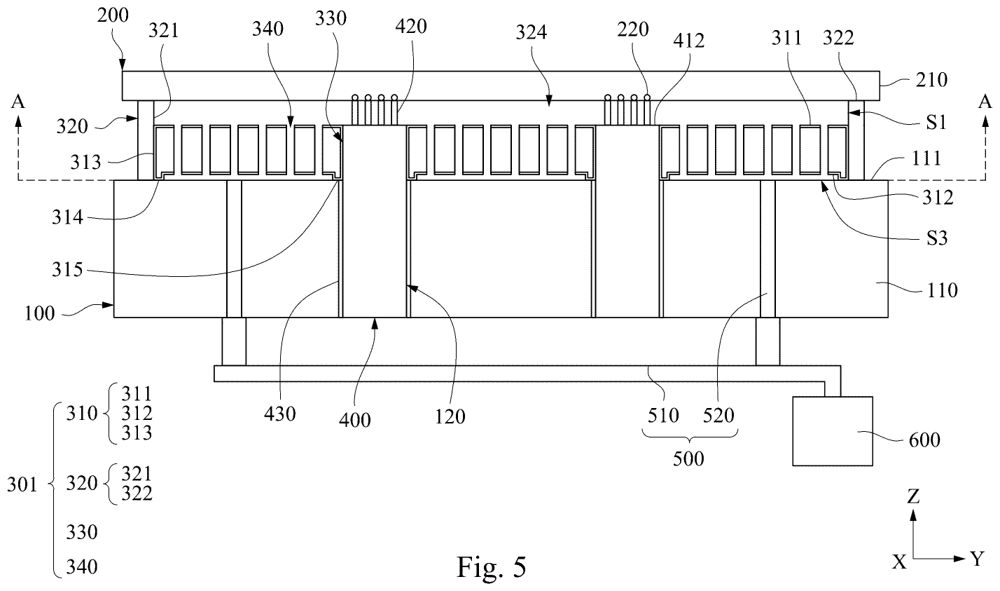

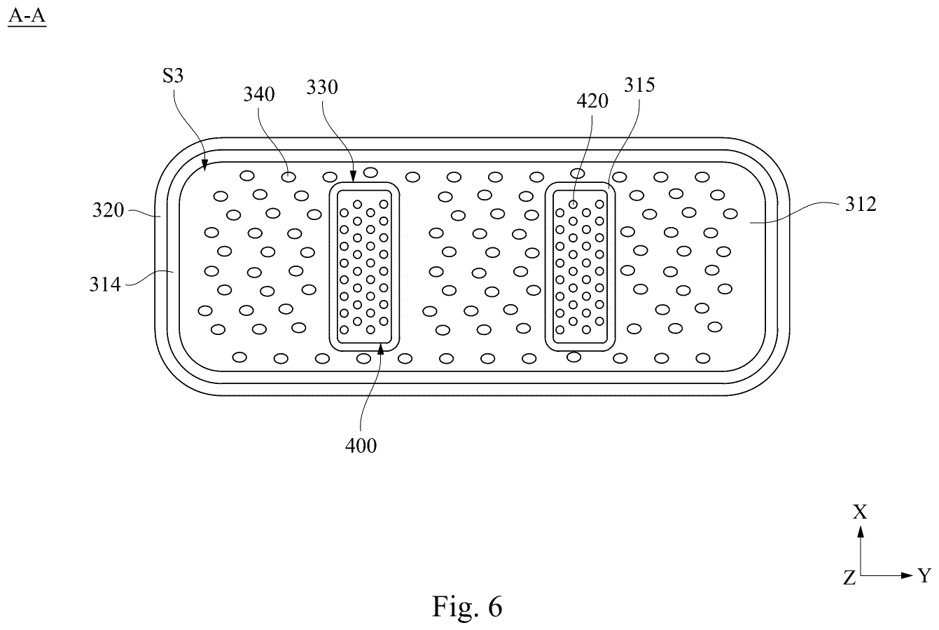

FIG. 5 is a sectional schematic view of an electronic test device 11 with negative-pressure-typed contact alignments according to one embodiment of the present disclosure. FIG. 6 is a cross-sectional view of FIG. 6 along a line AA. As shown in FIG. 5 and FIG. 6, the electronic test device 11 of this embodiment and the electronic test device 10 of the above-mentioned embodiment are substantially the same, except that, when the annular elastic structure 301 and the circuit load board 200 are large-size products and a gradual sink may be happened in the center thereof, the second surface 312 of the intermediate plate 310 might be partially contacted with the top portion 111 of the base 110, so as to strengthen the supporting strength of the test platform 100 for the annular elastic structure 301 and the circuit load board 200.

More specifically, the second surface 312 of the intermediate plate 310 is formed with an outer flange 314 and a plurality of annular flanges 315. The outer side 313 of the intermediate plate 310 is directly connected to the outer flange 314, and the outer side 313 of the intermediate plate 310 is connected to the outer flange 314, and the outer flange 314 completely surrounds the annular flanges 315. Each of the annular flanges 315 completely surrounds the contour of each of the through holes 330. Therefore, the base 110, the intermediate plate 310, the outer flange 314 and the annular flanges 315 together define the aforementioned second air gap S3, and the second air gap S3 is formed between the outer flange 314 and the annular flanges 315 (FIG. 6).

However, the present disclosure is not limited thereto. In other embodiments, one with ordinary skills in the field of the present disclosure may also implement the base 110, the intermediate plate 310, the outer flange 314 and these annular flanges 315 to jointly define a plurality of second air gaps S3 isolated from each other in different designs.

However, the present disclosure is not limited to the above-mentioned probe modules, the above-mentioned second air gap, the above-mentioned placement openings, the above-mentioned through holes and the above-mentioned annular flanges in numbers. In other embodiments, the above-mentioned probe modules, the above-mentioned second air gap, the above-mentioned placement openings, the above-mentioned through holes and the above-mentioned annular flanges may also be single.

Thus, through the construction of the embodiments above, the electronic test device with negative-pressure-typed contact alignments is able to make the circuit load board descending accurately and smoothly, so as to accurately complete the alignment of the probes of the probe head and the conductive contacts of the circuit load board, thereby improving the accuracy of the test performance.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. An electronic test device with negative-pressure-typed contact alignments, comprising:
a test platform;
a circuit load board loading and electrically connecting to a device under test;
an annular elastic structure sandwiched between the test platform and the circuit load board, so that an internal space that is enclosed by the annular elastic structure and sandwiched between the test platform and the circuit load board becomes airtight;
at least one probe module disposed on the test platform and partially extending into the internal space; and
an airway assembly disposed on the test platform and connected to the internal space,
wherein when the internal space is evacuated through the airway assembly so as to drive the circuit load board to compress the annular elastic structure and the internal space toward the test platform, the circuit load board is pressed to be electrically connected to the at least one probe module.

2. The electronic test device with negative-pressure-typed contact alignments of claim 1, wherein the annular elastic structure comprises:
an intermediate plate disposed between the test platform and the circuit load board, and located within the internal space; and
an elastic airtight ring enclosing the internal space, surrounding and fixedly connected to the intermediate plate, and sandwiched between the test platform and the circuit load board, so that a first air gap is jointly defined by the circuit load board, the intermediate plate and the elastic airtight ring, and a second air gap is jointly defined by the test platform, the intermediate plate and the elastic airtight ring, and the second air gap is in communication with the airway assembly; and
a plurality of vacuum channels distributed on the intermediate plate and respectively connected to the first air gap and the second air gap.

3. The electronic test device with negative-pressure-typed contact alignments of claim 2, wherein the first air gap is larger than the second air gap.

4. The electronic test device with negative-pressure-typed contact alignments of claim 2, wherein the vacuum channels are spaced arranged to surround the at least one probe module.

5. The electronic test device with negative-pressure-typed contact alignments of claim 2, wherein an outer side of the intermediate plate is directly connected to an inner side of the annular elastic structure and located between an upper side and a lower side of the annular elastic structure.

6. The electronic test device with negative-pressure-typed contact alignments of claim 2, wherein the test platform comprises at least one placement opening in which the at least one probe module inserted; and
the at least one probe module is further provided with an airtight collar sheathed around an outer surface of the at least one probe module so that the airtight collar is clamped between the at least one probe module and the test platform to disconnect a communication between the second air gap and the at least one placement opening.

7. The electronic test device with negative-pressure-typed contact alignments of claim 6, wherein the annular elastic structure comprises:
at least one through hole formed on the intermediate plate, connected to two opposite surfaces of the intermediate plate and coaxially aligned with the at least one placement opening,
wherein the at least one probe module is collectively inserted into the at least one through hole and the at least one placement opening.

8. The electronic test device with negative-pressure-typed contact alignments of claim 7, wherein one surface of the intermediate plate opposite to the circuit load board is formed with an outer flange and at least one annular flange; and
an outer side of the intermediate plate is connected to the outer flange, and the at least one annular flange surrounds a contour of the at least one through hole, wherein the second air gap is formed between the outer flange and the at least one annular flange.

9. The electronic test device with negative-pressure-typed contact alignments of claim 2, wherein the at least one probe module comprises a module body and a plurality of compression probes, each of the compression probes is retractably installed on an end surface of the module body; and
the circuit load board comprises a wiring board that is placed on the elastic airtight ring, and a plurality of contacts that are distributed on a bottom surface of the wiring board,
wherein when the circuit load board vertically presses the at least one probe module, the contacts respectively press the compression probes into the module body to be electrically contacted the compression probes.

10. The electronic test device with negative-pressure-typed contact alignments of claim 9, wherein each of the compression probes has a compression stroke, and a length of the compression stroke is the same as a height of the first air gap.

11. An electronic test device with negative-pressure-typed contact alignments, comprising:
a test platform;
a circuit load board loading and electrically connecting to a device under test;
an annular elastic structure sandwiched between the test platform and the circuit load board, wherein an internal space that is airtight is collectively formed by the test platform, the circuit load board and the annular elastic structure;
a plurality of vacuum channels formed on the annular elastic structure to be in communication with the internal space, respectively;
at least one probe module disposed on the annular elastic structure and partially extending into one part of the internal space between the annular elastic structure and the circuit load board; and
an airway assembly disposed on the test platform, and communicated with the part of the internal space through the vacuum channels,
wherein the airway assembly evacuates the internal space to allow the circuit load board to press and conduct to the at least one probe module.

12. The electronic test device with negative-pressure-typed contact alignments of claim 11, wherein the annular elastic structure comprises:
an intermediate plate disposed between the test platform and the circuit load board, and located within the internal space; and
an elastic airtight ring enclosing the internal space, surrounding and fixedly connected to the intermediate plate, and the elastic airtight ring sandwiched between the test platform and the circuit load board, so that a first air gap that is the part of the internal space is jointly defined by the circuit load board, the intermediate plate and the elastic airtight ring, and a second air gap is jointly defined by the test platform, the intermediate plate and the elastic airtight ring and in communication with the airway assembly.

13. The electronic test device with negative-pressure-typed contact alignments of claim 12, wherein the vacuum channels are spaced distributed on the intermediate plate to surround the at least one probe module, and each of the vacuum channels is connected to the first air gap and the second air gap, respectively.

14. The electronic test device with negative-pressure-typed contact alignments of claim 12, wherein the first air gap is larger than the second air gap.

15. The electronic test device with negative-pressure-typed contact alignments of claim 12, wherein an outer side of the intermediate plate is directly connected to an inner side of the annular elastic structure and located between an upper side and a lower side of the annular elastic structure,
wherein the upper side of the annular elastic structure is removably contacted with the circuit load board, and the lower side of the annular elastic structure is fixedly connected to the test platform.

16. The electronic test device with negative-pressure-typed contact alignments of claim 12, wherein the test platform comprises at least one placement opening in which the at least one probe module inserted;
the at least one probe module is further provided with an airtight collar sheathed around an outer surface of the at least one probe module so that the airtight collar is clamped between the at least one probe module and the test platform to disconnect a communication between the second air gap and the at least one placement opening; and
the annular elastic structure comprises at least one through hole formed on the intermediate plate, connected to two opposite surfaces of the intermediate plate and coaxially aligned with the at least one placement opening, wherein the at least one probe module is located within the at least one through hole and the at least one placement opening.

17. The electronic test device with negative-pressure-typed contact alignments of claim 16, wherein the annular elastic structure is formed with an outer flange and at least one annular flange, an outer side of the intermediate plate is connected to the outer flange, and the at least one annular flange surrounds a contour of the at least one through hole, wherein the second air gap is formed between the outer flange and the at least one annular flange.

18. The electronic test device with negative-pressure-typed contact alignments of claim 12, wherein the at least one probe module comprises a module body and a plurality of compression probes, each of the compression probes is retractably installed on an end surface of the module body; and
the circuit load board comprises a wiring board that is placed on the elastic airtight ring, and a plurality of contacts that are distributed on a bottom surface of the wiring board,
wherein when the circuit load board vertically presses the at least one probe module, the contacts respectively press the compression probes into the module body to be electrically contacted the compression probes.

19. The electronic test device with negative-pressure-typed contact alignments of claim 18, wherein each of the compression probes has a compression stroke, and a length of the compression stroke is the same as a height of the first air gap.
